(19) United States
(12) Patent Application Publication
(10) Pub. No.: US 2004/0245090 A1
(43) Pub. Date: Dec. 9, 2004

(54) Process for manufacturing multilayer systems

(76) Inventors: Andrey E. Yakshin, Nieuwegein (NL); Frederik Bijkerk, Amsterdam (NL); T.P.C. Klaver, Leiden (NL); Eric Louis, Ijsselstein (NL)

Correspondence Address: Hudak Shunk & Farine, 2020 Front Street, Suite 307, Cuyahoga Falls, OH, 44221, US

(21) Appl. No.: 10/493,336

(22) PCT Filed: Oct. 24, 2001
(86) PCT No.: PCT/EP01/12305

(51) Int. Cl. C23C 14/30; G03F 9/00; C23C 14/00; C23C 14/32

(52) U.S. Cl. 204/192.1; 430/5; 427/596; 204/192.11

(57) ABSTRACT

The invention relates to a process for manufacturing multilayer systems for mirrors in the extreme ultraviolet and x-ray wavelength range, whereby at least one layer, in particular made of Mo, Si, Ru, C., B, Rb, Sr, Y, Cr, Sc or components thereof, is at least partly deposited with ion-beam assistance. In order to improve the surface properties of multilayer systems and to achieve the highest possible reflectivity the ion energy of the ion-beam is selected as an energy equivalent to or below the layer's sputtering threshold.

### DESCRIPTION

The present invention relates to a process for manufacturing multilayer systems on a substrate for mirrors in the extreme ultraviolet and x-ray wavelength range, whereby at least one layer, in particular made of Mo, Si, Ru, C, B, Rb, Rh, Sr, Y, Cr, Sc or components thereof, is at least partly applied by ion-beam assisted deposition. The present invention also relates to a process for manufacturing multilayer systems, in particular for mirrors in the extreme ultraviolet and x-ray wavelength range, whereby at least one layer is irradiated with ions after being deposited.

Multilayer systems are used to reflect shortwave electromagnetic rays, e.g. in the extreme ultraviolet and x-ray wavelength range. The extreme ultraviolet wavelength range (EUV) is the transition range between the ultraviolet and the x-ray range and generally comprises the wavelengths from app. 30 nm to app. 10 nm. For example, in EUV lithography wavelengths of. app. 13 nm are, in particular, used. The simplest multilayer systems consist of two different materials, i.e. an absorbing and a reflecting material. The advantage of multilayer systems is the fact that the intensity of radiation which is reflected in phase at different boundary surfaces is increased by constructive interference.

Currently magnetron sputtering, ion-beam sputtering, laser and e-beam evaporation are successfully being applied. The first three methods have the general disadvantage of the presence of energetic particles in the flux of material being deposited, particles that damage the interfaces of the layers in the multilayer structure being grown. In contrast, e-beam evaporation provides a flux of low energy particles, mainly particles of the material being deposited. To smoothen the layers, ion beam sputtering, i.e. involving removal of material, is used immediately after deposition of each of the layers. The application of the ions in this classical sputtering or etching regime has a number of disadvantages connected to the non-uniformity of the ion flux produced by existing ion guns. As an alternative method, ion-beam treatment can be applied during growth of the films, a method which is known as ion-beam assisted deposition (IAD).

It is examined in more detail in P. J. Martin, Journal of Materials Science 21 (1986) 1-25 as regards the growth of dielectrical oxide films and diamond-type carbon films, and in E. J. Puik, Applied Surface Science 47 (1991) 251-260 as regards the production of multilayer systems of tungsten/carbon, nickel/carbon and tungsten/silicon in the manufacture of x-ray mirrors.

As explained by P. J. Martin, ion beams are used to sputter deposition material, control the deposition of the ionized vapor as regards spatial distribution and add activation energy or chemical activity to the growing film. The ions are deployed in a plasma or in a high vacuum and display kinetic energies over the entire range from some eV up to several hundred eV. As regards the kinetic energy of the assisting ions, P. J. Martin states that the energy should optimally be below the energy threshold at which the sputter yield equals 1 atom per ion.

P. J. Martin in particular reports on experiments concerning the deposition of titanium oxides. In the context of the IAD process, argon ions of 400 eV, oxygen ions of 300 eV as well as mixtures of argon and oxygen ions of 400 eV in one case and 300 eV in another case were used. By irradiation with ions of higher energy, higher extinction coefficients of the grown films were achieved. Titanium oxides generated by IAD had higher refraction indices than titanium oxides deposited by conventional processes.

E. J. Puik et al. examined, by reference to the system nickel/carbon, to what extent the addition of an ion beam affects the result in electron beam evaporation. Argon ions of 200 eV were used as the ion beam. The reflectivity of nickel/carbon multilayer systems was examined. Both the nickel and the carbon layers had thicknesses of 1.4 nm. Carbon was deposited in all cases without ion beam assistance by means of electron beam evaporation.

A first reference sample was produced by conventional electron beam evaporation of the nickel. The argon ion beam was switched on in the second sample after the nickel layer already had a thickness of 0.9 nm. In the third sample the argon ion beam was already switched on at a layer thickness of 0.5 nm. In the last sample the entire nickel layer was deposited by IAD.

At a wavelength of 3.16 nm, sample 2 displayed a reflectivity twice as high as in reference sample 1. At a small number of layers, sample 3 displayed reflectivities comparable to those of sample 2; at higher layer numbers the reflectivity approximated that of reference sample 1. The deposition of sample 4 had to be terminated before completion. It showed very low reflectivity.

These results are attributed to the fact that the mean penetration depth of the argon ions was app. 0.4 nm at 200 eV. Although a smoothing effect occurs on the sample surface, a mixing induced by argon ions can occur on the boundary surface between nickel and carbon, which results in lower reflectivity at this boundary surface.

The problem of the present invention is to provide a process by which multilayer systems with improved surface properties and, consequently, with the highest possible reflectivities can be manufactured.

This problem is solved by a process according to claim 1. The problem is additionally solved by a process according to claim 6.

It is a common feature of both processes that the energy of the ions of the assisting ion beam is set at a specific energy range. This range is limited at the top end by the threshold sputtering energy. The threshold sputtering energy varies depending on material. It is defined as the energy of the initial bombarding ion-particles at which sputtering of the atoms or molecules of the layer does not occur. As the moment at which sputtering does not occur cannot exactly be determined, the threshold sputtering energy is in fact the energy of the initial bombarding particles where the sputtering is negligibly low, i.e. where less than 0.1% of the layer material is removed. The energy range is limited at the bottom end by the minimum energy which must be transmitted to the atoms resp. molecules to be deposited to provide surface mobility.

In a preferred embodiment the ion-energy corresponds to 4 to 10 time U with U being the binding energy of the layer material to be treated.

For example, the binding energy of the atoms in Mo layer is U ˜9 eV. If the ion-energy is 4·U=36 eV the probability of the event of sputtering is extremely low, almost zero. Within the range up to 10·U=90 eV the sputtering effect is negligibly low and only around 0.1% or less of the layer material is removed.

The method is focused on the application to EUV Lithography and the materials therefor preferably concern, but are not limited to Mo, Si, MoₓSi_{y}, SiOₓ, Mo₂C, Ru, C, B₄C, SiC, Rb, RbH, Rb₂S, Rh, Sr, Y, Cr, Sc with x and y=1, 2 or 3.

Irradiation with ions in such an energy range ensures that no material or only a negligible quantity of the deposited layer is removed by the ions. Instead, energy is transmitted to the atoms resp. molecules on the surface which increases their mobility. In most cases of materials the depth in which the atoms or molecules are mobilized generally amounts to one or two monolayers. The surface mobility of the atoms resp. molecules achieves a smoothing effect since the atoms resp. molecules on the surface even out high spatial frequency surface roughness (HSRF) by their movements. In particular when using the multilayer systems manufactured by the process according to the invention for mirrors in the extreme ultraviolet wavelength range, this improved surface quality is very important because it is accompanied by higher reflectivities. Along with reduced roughness the process according to the invention improves the homogeneity of the layer in the plane. This allows one to better control the density of the layer and therefore its optical constants, leading to higher reflectivity.

The option of adjusting the optical refracting properties of the individual layers and hence of the entire multilayer system by means of the processes according to the invention by inducing a change of materials density is particularly attractive. In addition, the stress in individual layers can be reduced, and controlled in such a way that the stress in adjacent layers is partly or fully compensated resulting in near zero stress for the entire coating. This way, the multilayer will not distort the shape of substrate which is a key demand for the precision EUVL optics, whereby the lifetime of the entire multilayer system can be increased.

It is a further advantage of the processes according to the invention that they do not lead to a deviation of the period near the positions of the substrate mounting clamps due to resputtering of the clamping materials, as is the case in conventional processes. This allows to obtain the mirror with a working surface in the area near the clamps.

Deposition of a layer may be already performed by ion beam assisted deposition. In this case it has proven advantageous to deposit the entire layer ion beam assisted, i.e. the process time of the ion-beam application corresponds to the time that the layer is grown. However, this is not compulsory and the ion beam application can also be performed during a fraction of the growth process of the layer. It has, however, also proven advantageous to add the ion beam assistance only from a certain layer thickness onward, e.g. some nanometers.

In case this partial treatment is too short in order to achieve smoothing effects, a further irradiating of layer with ions can be done after it has been deposited.

Another modification allows to perform the ion beam application only during deposition of the top part of the layer to minimize the risk of materials intermingling. The first part of the layer is deposited without ion assistance and the ion treatment is applied after the film having reached a certain thickness. For most materials that thickness will be 1 to 2 nm.

Another preferred embodiment of the process concerns the ion treatment only during deposition of the first atomic monolayers in the layer to deliberately create an intermixed or compound material interface.

Another embodiment consists of treatment of the film with these low-energy ions after the layer has been deposited. This is the process of ion-induced redistribution of surface atoms (IRSA). This process can be applied for very thin films (e.g. due to the design of the multilayer), or in the case ion assistance during growth is not sufficiently effective to smoothen the layer.

The energy of the ions for IRSA is again below the sputtering threshold but high enough to provide surface mobility of the atoms (i.e. 50 to 80 eV for most materials). The time of IRSA is chosen such to provide enough smoothening of the surface. As a result, no material is removed due to the ion application in the methods described, an essential feature of both methods.

According to another embodiment of the invention at least one layer of the multilayer system is deposited without ion beam assistance and is irradiated with ions after being deposited. The energy range is identical to the energy range of the ions used during growth of the layer. As a particular case very thin layers can be grown without ion assistance followed by past deposition irradiation with ions. This way one could avoid intermixing effects induced at the boundary with the previous layer and still achieve a good smoothening effect.

A further advantage is that non-uniformities in the ion beam profile do not have the negative effect they possess in conventional processes. In conventional ion beam-assisted processes sputter effects of different impact occur in different substrate locations, depending on the spatial distribution of the non-uniformities. In the processes according to the invention, sputter effects do not occur.

Apart from non-uniformity caused by non-ideal ion beam profile, polishing of curved surfaces in the conventional process usually results in additional non-uniformity connected to the fact that ions strike the surface at different angles at different locations at the substrate. In the process according to the invention this type of non-uniformity will not occur. As a result the claimed method does not introduce additional non-uniformity in case of both flat and curved substrates.

For industrial application, it is particularly advantageous that the production times of multilayer systems are shorter in the processes according to the invention than in conventional processes in which material is first deposited and then partly removed again by ion etching.

In treating molecule layers with the processes according to the invention, it must further be observed when selecting the ion energy that preferential sputter directions can occur near to the sputter threshold energy. In this case, the ion energy should be reduced further.

During deposition it has also proved advisable to move the ion beam across the substrate or fan out the ion beam so far that the entire surface to be coated is irradiated. The most preferred embodiment is an ion-beam having diameter and shape to match the size of the substrate to be coated.

Essential is that the method is not limited to flat substrates and can equally well be applied to substrates curved with any geometry. The effect of the ion beam is identical so that on flat substrates, and essential is that no material is removed so that the lateral deposition profile of the evaporation process itself (e.g. electron beam evaporation) is not affected. The fact that there are no special provisions or mask systems needed for curved elements makes it attractive over other methods that generally face a considerable higher complexity when applied to curved elements.

Layers are preferably applied by electron beam evaporation, magnetron sputtering or ion beam sputtering.

Application of the method leads to smoother layers, but also to the annihilation of voids and defects, and thus, to a compaction of the layer and rearrangement of the positions of the atoms. Since this has an influence on the internal stress of the multilayer films, the method in principle allows a control of the stress.

The same argument is valid for the materials density and therefore on the optical properties.

Conventional ion bombardment results in sputtering of material and will therefore change the layer thickness. If the ion-beam is not uniform, the sputter-effect will not be uniform; To prevent this, conventional methods require masking of the ion-fluxes, making the flux uniform. Laterally graded coating require masking for a pre-determined flux profile. The use of ions according to the invention circumvents this disadvantage since sputtering does not take place, and therefore does not need masking. This avoids the need for preparing and optimizing masks.

Silicon and molybdenum applied alternately are especially preferred layer materials. In particular mirrors for the extreme ultra-violet range are made of silicon and molybdenum layers.

The invention is now explained in more detail by reference to the following examples:

Four samples were made of molybdenum and silicon. The ion energy used in all four samples was between 50 eV and 100 eV. At these energies around 0,1% or less of the deposited material is removed. Their reflectivity was subsequently measured at a wavelength of 12.9 nm.

In the first sample the ion beam current was 25 mA. Argon gas was switched on the whole time. From 40 percent of the desired layer thickness on, the molybdenum layers were deposited with the assistance of an argon ion beam by means of electron beam evaporation; the same applied to the silicon layers from 20 percent of the desired layer thickness. The measured maximum reflectivity was 67.4 percent.

In the second sample the ion beam current was also 25 mA. Argon gas was only switched on during the period of ion beam assistance. The molybdenum was deposited with ion beam assistance by electron beam evaporation from 50 percent of the desired layer thickness on, and the silicon from 60 percent of desired layer thickness on. The maximum reflectivity was 67.8 percent.

In the third sample the ion beam current was 50 mA. Krypton gas was only switched on during ion beam assistance. The molybdenum was deposited with ion beam support from 50 percent and the silicon from 60 percent of the desired layer thickness on. The maximum reflectivity was 68.7 percent.

In the fourth sample the ion beam current was 50 mA. Krypton gas was only switched on during ion beam assistance. The molybdenum was deposited with ion beam assistance from 50 percent of the desired layer thickness on. The silicon was deposited without ion beam assistance by electron beam evaporation after which the layer was irradiated with ions for 30 seconds. The maximum reflectivity was 67.9 percent.

Although the substrates were curved, the relative error in layer thickness was only ±0.05 percent. This corresponds to an absolute error of ±0.3 nm, i.e. the size of an atomic monolayer.

Maximum reflectivities of comparable samples deposited without ion beam support are app. 64 percent at a wavelength of 12.9 nm.

1. A process for manufacturing multilayer systems on a substrate for mirrors in the extreme ultraviolet and x-ray wavelength range, comprising the steps of: at least partly depositing with ion beam assistance at least one layer in particular made of Mo, Si, Ru, C, B, Rb, Rh, Sr, Y, Cr, Sc or components thereof, and wherein an energy equivalent to or below a sputtering threshold of the layer is selected as the ion energy of the ion beam.

2. A process according to claim 1, wherein the ion energy corresponds to 4 to 10 times U with U being the binding energy of the layer material to be treated.

3. A process according to claim 1, wherein a process time of the ion beam application corresponds to a time that the layer is grown.

4. A process according to claim 1 wherein the ion beam application is performed during a fraction of the growth process of the layer.

5. A process according to claim 1, wherein after at least one layer has been deposited with ion beam support, the layer is further irradiated with ions for some period of time before proceeding with the next layer.

6. A process for manufacturing multilayer systems on a substrate for mirrors in the extreme ultraviolet and x-ray wavelength range, comprising the steps of: depositing at least one layer without ion beam assistance and irradiating the layer with ions after being deposited, wherein an energy equivalent to or below a sputtering threshold of the layer is selected as the ion energy.

7. A process according to claim 1, wherein diameter and shape of the ion beam match the size of the substrate to be coated, or wherein the layers are deposited by electron beam evaporation, magnetron sputtering or ion beam sputtering, or a combination thereof.

8. (Cancelled).

9. A process according to claim 2, wherein a process time of the ion beam application corresponds to a time that the layer is grown.

10. A process according to claim 2, wherein the ion beam application is performed during a fraction of the growth process of the layer.

11. A process according to claim 2, wherein after at least one layer has been deposited with ion beam support, the layer is further irradiated with ions for some period of time before proceeding with the next layer.

12. A process according to claim 3, wherein after at least one layer has been deposited with ion beam support, the layer is further irradiated with ions for some period of time before proceeding with the next layer.

13. A process according to claim 4, wherein after at least one layer has been deposited with ion beam support, the layer is further irradiated with ions for some period of time before proceeding with the next layer.

14. A process according to claim 9, wherein after at least one layer has been deposited with ion beam support, the layer is further irradiated with ions for some period of time before proceeding with the next layer.

15. A process according to claim 10, wherein after at least one layer has been deposited with ion beam support, the layer is further irradiated with ions for some period of time before proceeding with the next layer.

16. A process according to claim 2, wherein diameter and shape of the ion beam match the size of the substrate to be coated, or wherein the layers are deposited by electron beam evaporation, magnetron sputtering or ion beam sputtering, or a combination thereof.

17. A process according to claim 3, wherein diameter and shape of the ion beam match the size of the substrate to be coated, or wherein the layers are deposited by electron beam evaporation, magnetron sputtering or ion beam sputtering, or a combination thereof.

18. A process according to claim 4, wherein diameter and shape of the ion beam match the size of the substrate to be coated, or wherein the layers are deposited by electron beam evaporation, magnetron sputtering or ion beam sputtering, or a combination thereof.

19. A process according to claim 5, wherein diameter and shape of the ion beam match the size of the substrate to be coated, or wherein the layers are deposited by electron beam evaporation, magnetron sputtering or ion beam sputtering, or a combination thereof.

20. A process according to claim 6, wherein diameter and shape of the ion beam match the size of the substrate to be coated, or wherein the layers are deposited by electron beam evaporation, magnetron sputtering or ion beam sputtering, or a combination thereof.

21. A process according to claim 9, wherein diameter and shape of the ion beam match the size of the substrate to be coated, or wherein the layers are deposited by electron beam evaporation, magnetron sputtering or ion beam sputtering, or a combination thereof.

22. A process according to claim 10, wherein diameter and shape of the ion beam match the size of the substrate to be coated, or wherein the layers are deposited by electron beam evaporation, magnetron sputtering or ion beam sputtering, or a combination thereof.

23. A process according to claim 11, wherein diameter and shape of the ion beam match the size of the substrate to be coated, or wherein the layers are deposited by electron beam evaporation, magnetron sputtering or ion beam sputtering, or a combination thereof.

24. A process according to claim 12, wherein diameter and shape of the ion beam match the size of the substrate to be coated, or wherein the layers are deposited by electron beam evaporation, magnetron sputtering or ion beam sputtering, or a combination thereof.

25. A process according to claim 13, wherein diameter and shape of the ion beam match the size of the substrate to be coated, or wherein the layers are deposited by electron beam evaporation, magnetron sputtering or ion beam sputtering, or a combination thereof.

26. A process according to claim 14, wherein diameter and shape of the ion beam match the size of the substrate to be coated, or wherein the layers are deposited by electron beam evaporation, magnetron sputtering or ion beam sputtering, or a combination thereof.

27. A process according to claim 15, wherein diameter and shape of the ion beam match the size of the substrate to be coated, or wherein the layers are deposited by electron beam evaporation, magnetron sputtering or ion beam sputtering, or a combination thereof.
